(19) United States
(12) Patent Application Publication
(10) Pub. No.: US 2010/0231422 A1
(43) Pub. Date: Sep. 16, 2010

(54) TOUCH PANEL

(75) Inventors: Kazuhisa Inaba, Tokyo (JP); Noriyuki Yasuda, Tokyo (JP); Masutatsu Mashimo, Tokyo (JP)

Correspondence Address: OLIFF & BERRIDGE, PLC, P.O. BOX 320850, ALEXANDRIA, VA, 22320-4850, US

(73) Assignee: TDK CORPORATION, TOKYO (JP)

(21) Appl. No.: 12/721,126

(22) Filed: Mar. 10, 2010

(30) Foreign Application Priority Data
Mar. 16, 2009 (JP) 2009-063149

(51) Int. Cl. H03K 17/94

(52) U.S. Cl. 341/20

(57) ABSTRACT

The invention provides a touch panel that can satisfactory support opposing electrodes while reducing variation in the input load value between the perimeter and center sections. The touch panel of the invention has a lower electrode comprising a first transparent base and a first transparent conductive layer laminated on the first transparent base, and an upper electrode comprising a second transparent base and a second transparent conductive layer laminated on the second transparent base, which are mutually opposing in such a manner that the first transparent conductive layer and second transparent conductive layer face each other, the lower electrode and upper electrode being laid facing each other partially sandwiching a bonding member, and the bonding member comprises a first adhesive layer composed of a first resin and a second adhesive layer composed of a second resin.

### BACKGROUND OF THE INVENTION

1. Field of the Invention

The present invention relates to a touch panel.

2. Related Background Art

Resistance film-type touch panels are known that have a structure with a pair of electrodes, each comprising a transparent conductive layer on a transparent base, laid together so that the transparent conductive layers are facing each other (see Japanese Unexamined Patent Publication No. 2003-29930).

In such touch panels, one of the electrodes is pressed to contact the other electrode and create current between the transparent conductive layers, thereby allowing detection of the location that has been pressed.

### SUMMARY OF THE INVENTION

In these touch panels, a pair of electrodes are laid facing each other across a bonding member around their perimeters, whereby they are supported in such a manner that the opposing electrodes are separate from each other in the absence of pressing force. When touch panels of this type in the prior art have been pressed to obtain conduction, it has been necessary to apply greater pressing force around the perimeter of the touch panel where the bonding member is sandwiched between the perimeter, than near the center where the electrodes are more susceptible to bending. Consequently, conventional touch panels have generally had a large variation in the pressing force (input load value) necessary for contact between opposing electrodes.

The variation in input load value is preferably as small as possible for stabler management of touch panels. One method for reducing the input load value around the perimeter involves the use of a more flexible resin than the prior art as the bonding member, or narrowing the width of the bonding member. However, it is difficult to adequately support opposing electrodes with such methods, and as a result bending occurs even in the absence of pressing, causing contact between the electrodes, or the electrodes may peel from the bonding member.

The present invention has been accomplished in light of these circumstances, and its object is to provide a touch panel that can reduce variation in the input load value while ensuring satisfactory support between opposing electrodes.

In order to achieve the object stated above, the touch panel of the invention has a lower electrode comprising a first transparent base and a first transparent conductive layer laminated on the first transparent base, and an upper electrode comprising a second transparent base and a second transparent conductive layer laminated on the second transparent base, which are mutually opposing in such a manner that the first transparent conductive layer and second transparent conductive layer face each other, the touch panel being characterized in that the lower electrode and upper electrode are laid facing each other partially sandwiching a bonding member, and the bonding member comprises a first adhesive layer composed of a first resin and a second adhesive layer composed of a second resin that is softer than the first resin.

The bonding member used to attach the lower electrode and upper electrode in the touch panel of the invention has a plurality of layers including a first adhesive layer and second adhesive layer, composed of resins of different hardnesses. Such a bonding member can adequately maintain the spacing between the first electrode and second electrode due to the hard first adhesive layer, thus preventing their contact in the absence of pressing force. At the same time, flexible deformation can occur at the soft second adhesive layer sections in response to bending of the electrodes, thus minimizing increase in the input load value near the bonding member in comparison to the center section. As a result, satisfactory support can be ensured between the lower electrode and upper electrode while variation in the overall input load value can be reduced.

The bonding member in the touch panel of the invention is preferably formed so that the first adhesive layer and second adhesive layer are separated in the thickness direction. The bonding member will thus have a region of thickness composed of the flexible second adhesive layer, so that deformation from its original shape will be facilitated at that section. As a result, deformation can more easily occur in response to bending of the electrodes, and the input load value near the bonding member can be further reduced.

The first adhesive layer in the touch panel of the invention preferably has a small width on either the lower electrode or upper electrode, as compared to the other one, in a cross-section along the widthwise direction of the bonding member, and the second adhesive layer is preferably formed in a manner filling at least the section of reduced width of the first adhesive layer in that cross-section.

A bonding member having this construction has a smaller first adhesive layer width and a greater amount of the soft second adhesive layer provided on one electrode side, and it can therefore deform in a flexible manner in response to bending of the electrode by pressing force on that electrode side.

The first adhesive layer is preferably formed so that the thickness (the height of the cross-section) decreases from the outside to the inside of the touch panel. This will help create deformation in the bonding member on the side of the upper electrode which is pressed, thus facilitating bending of the upper electrode. As a result, the input load value near the bonding member can be further reduced.

The first adhesive layer most preferably has a shape with an arched cross-section. Since the second adhesive layer of the bonding member will thus be provided filling the sections where the width of the first adhesive layer is reduced, a soft second adhesive layer will be formed on both sides of the arched hard first adhesive layer.

In a bonding member having this construction, the second adhesive layer on the inside of the first adhesive layer is easily compressed in response to bending of the upper electrode when the upper electrode is pressed, while the second adhesive layer on the outside is easily stretched in response to movement of the edges (shifting at the top and center) of the upper electrode that occurs with bending. As a result, satisfactory adhesion can be maintained between the bonding member and upper electrode while the input load value can be even more advantageously reduced. Since the second adhesive layer on the outside of the first adhesive layer seeks restoration from a stretched state, this type of bonding member facilitates restoration of the upper electrode to its original shape after pressing.

According to the invention it is possible to provide a touch panel that can reduce variation in the input load value while ensuring satisfactory support between opposing electrodes.

### BRIEF DESCRIPTION OF THE DRAWINGS

FIG. 1 is an exploded perspective view showing a touch panel according to a preferred embodiment.

FIG. 2 is an illustration that schematically shows the cross-sectional structure of the touch panel of FIG. 1 along line II-II.

FIG. 3 is a cross-sectional magnified view of the section around the bonding member of the touch panel of another embodiment.

FIG. 4 is a cross-sectional magnified view of the section around the bonding member of the touch panel of another embodiment.

FIG. 5 is a graph plotting required input load value with respect to distance from the edge.

### DESCRIPTION OF THE PREFERRED EMBODIMENT

Preferred embodiments of the invention will now be explained with reference to the accompanying drawings. Throughout the explanation of the drawings, corresponding elements will be referred to by like reference numerals and will be explained only once. Also the dimensional proportions depicted in the drawings are not necessarily limitative.

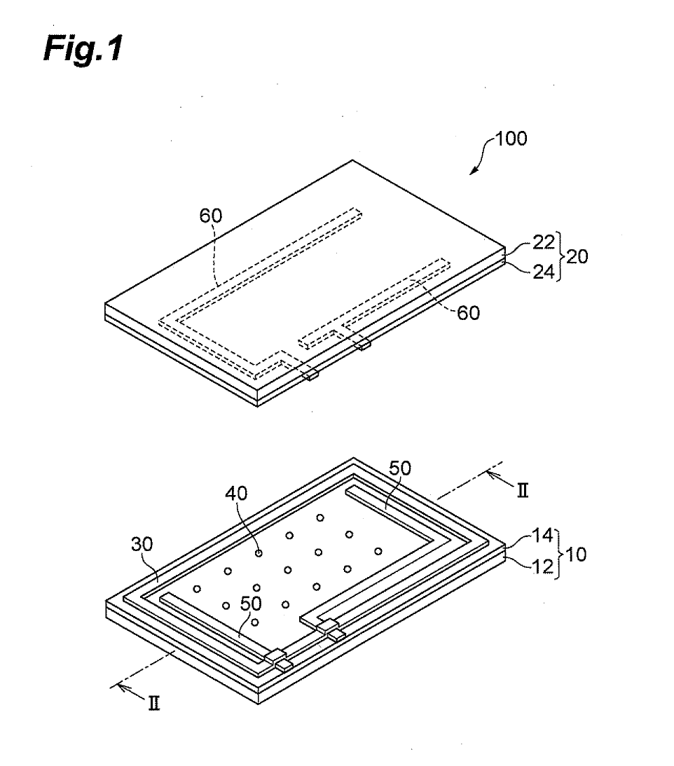

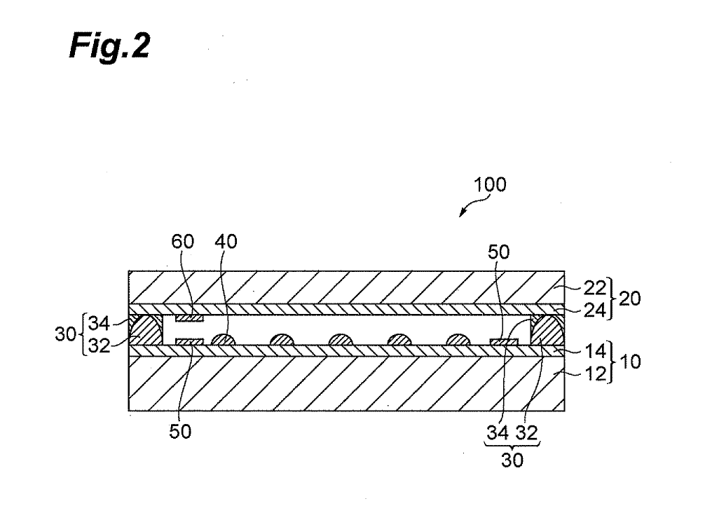

FIG. 1 is an exploded perspective view showing a touch panel according to a preferred embodiment, and FIG. 2 is a schematic illustration of the cross-sectional structure of the touch panel of FIG. 1 along line II-II. As seen in FIGS. 1 and 2, the touch panel 100 of this embodiment has a structure wherein a lower electrode 10 comprising a transparent conductive layer 14 (first transparent conductive layer) laminated on a transparent base 12 (first transparent base) and an upper electrode 20 comprising a transparent conductive layer 24 (second transparent conductive layer) laminated on a transparent base 22 (second transparent base) are situated in a mutually opposing manner with their transparent conductive layers 14, 24 facing each other.

The lower electrode 10 and upper electrode 20 are situated facing each other with a bonding member 30 sandwiched between the transparent conductive layer 14 and transparent conductive layer 24. The bonding member 30 is provided along the perimeter of the touch panel 100. Thus, the upper electrode member 10 and lower electrode member 20 are placed apart in such a manner that the transparent conductive layer 14 and transparent conductive layer 24 are not in contact in the absence of pressing force. The bonding member 30 may be provided only along part of the edge of the touch panel 100 instead of the entire perimeter as shown in the drawing. The bonding member 30 has a construction comprising the first adhesive layer 32 and second adhesive layer 34, as shown in FIG. 2. The detailed structure of such a bonding member 30 will be explained below.

A pair of extraction electrodes 50 composed of a conductive material such as a metal (for example, Ag) are provided on the inner surface of the transparent conductive layer 14 in the lower electrode member 10. The pair of extraction electrodes 50 have sections that are situated parallel along a pair of opposing sides of the touch panel 100, and sections each extending from the parallel sections to one side of the lower electrode member 10. There is also formed in the inside surface of the transparent conductive layer 24 in the upper electrode member 20, a pair of extraction electrodes 60 having sections situated parallel to each other and sections each extending therefrom to one side of the upper electrode member 20.

The parallel sections of the extraction electrodes 50 and the parallel sections of the extraction electrodes 60 are in a positional relationship with mutually crossing, and preferably orthogonal, directions. This allows horizontal/vertical positional detection when the touch panel 100 is completed. The extraction electrodes 50 and extraction electrodes 60 extend to the same side of the touch panel 100, in such a manner allowing easy external connection at those sections.

On the transparent conductive layer 14 (the side opposite the upper electrode 20) of the lower electrode 10 there are provided a plurality of dot spacers 40 to avoid unintended contact between the lower electrode 10 and upper electrode 20 in the absence of pressing. When the lower electrode 10 and upper electrode 20 are sufficiently supported by the bonding member 30, such dot spacers 40 may not be necessary.

The transparent bases 12, 22 are composed of a material that is transparent to visible light. As examples of the transparent bases 12, 22 there may be mentioned bases made of polyester resins such as polyethylene terephthalate (PET), polyolefin resins such as polyethylene and polypropylene, or polycarbonate resins, acrylic resins, norbornane-based resins (ARTON by JSR, ZEONOR by Zeon Corp., and the like), and polyethersulfone (PES). Glass may also be used instead of these resins. The transparent bases 12, 22 are not limited to those mentioned above and may be made of different types of transparent base materials.

The upper electrode 20 in the touch panel 100 is placed on the front side of the display device, which is the side that is pressed during use. Therefore, at least the transparent base 22 is preferably made of a resin film. This will appropriately reduce the stiffness of the transparent base 22, thereby facilitating bending of the upper electrode 20 by pressing force and resulting in a smaller input load value and easier operation of the touch panel 100. The transparent base 12 on the lower electrode 10 side may be a resin film or glass as suitable, but a resin film may allow smaller thickness and lighter weight to be achieved.

The transparent conductive layers 14, 24 are composed of conductive materials that are transparent to visible light, such as a transparent conductive oxide, for example. As transparent conductive oxides there may be mentioned indium oxide or indium oxide doped with one or more elements selected from among tin, zinc and tellurium, tin oxide or tin oxide doped with one or more elements selected from among antimony, zinc and fluorine, zinc oxide or zinc oxide doped with one or more elements selected from among aluminum, gallium, indium and boron, and titanium oxide doped with one or more elements selected from among niobium, molybdenum and tantalum. Conductive polymers may also be used instead of oxides. Tin-doped indium oxide (ITO) is suitable as the structural material for the transparent conductive layers 14, 24. The transparent conductive layers 14, 24 may also be layers with a structure in which powder composed of ITO or other transparent conductive particles is fixed with a resin. The dot spacer 40 is made of an insulating resin that is transparent to visible light, such as a photocuring resin.

As mentioned above, the bonding member 30 is composed of a first adhesive layer 32 and a second adhesive layer 34 formed over the first adhesive layer 32. The first adhesive layer 32 is made of a first resin, and the second adhesive layer 34 is made of a second resin that is softer than the first resin. These are formed separately in the thickness direction of the bonding member 30 in such a manner that the first adhesive layer 32 is unevenly distributed on the lower electrode 10 side and the second adhesive layer 34 is unevenly distributed on the upper electrode 20 side.

That the first adhesive layer 32 and second adhesive layer 34 are “formed separately in the thickness direction” means that the boundary separating the region of the first adhesive layer 32 and the region of the second adhesive layer 34 (the interface, or another layer present between these layers) is formed crossing the thickness direction of the bonding member 30 (the facing direction between the lower electrode 10 and upper electrode 20). If the bonding member 30 has such a boundary in at least some sections, the first adhesive layer 32 and second adhesive layer 34 may be said to have sections “formed separately in the thickness direction”.

More specifically; the first adhesive layer 32 of the bonding member 30 has an arched shape in the cross-section along the widthwise direction of the bonding member 30, and it is formed in such a manner that the width of the cross-section decreases from the lower electrode 10 side toward the upper electrode 20. The first adhesive layer 32 contacts the lower electrode 10 on the bottom part while contacting the upper electrode 20 at the top part. Since the first adhesive layer 32 thus contacts both the lower electrode 10 side and the upper electrode 20, the hard first adhesive layer 32 adequately supports the lower electrode 10 side and the upper electrode 20 to prevent contact between the opposing electrodes when the bonding member 30 is deformed in the absence of pressing force.

The second adhesive layer 34 of the bonding member 30 is formed filling the sections where the width of the cross-section of the first adhesive layer 32 is reduced. The bonding member 30 therefore has a uniform width in the height direction, due to the first adhesive layer 32 and second adhesive layer 32. As a result, the bonding member 30 is in contact with the lower electrode 10 and upper electrode 20 with approximately the same area, in a satisfactorily bonded state with both electrodes.

The “widthwise direction” of the bonding member 30 is the widthwise direction with respect to the length direction when it is formed in a linear shape having a prescribed lengthwise direction, as when the bonding member 30 is formed along the perimeter of the touch panel 100 as in this embodiment, while the cross-section vertical to this lengthwise direction corresponds to the “widthwise cross-section”. Instead of a linear form, the bonding member 30 may be formed as a plurality of spots with approximately the same lengths and widths, in which case the “widthwise direction” may be any direction, and any cross-section along the direction of height of the bonding member 30 corresponds to the “widthwise cross-section”.

The second resin composing the second adhesive layer 34 is softer than the first resin composing the first adhesive layer 32. The hardnesses of the first and second resins are their hardnesses in the first adhesive layer 32 and second adhesive layer 34. For example, when the first and second resins are curable resins and they are in the first adhesive layer 32 or second adhesive layer 34 in their cured state, the hardnesses of the first and second resins are their hardnesses in their cured state.

The hardness for the first and second resins can be expressed in terms of their Young's modulus, for example, and the Young's modulus of the second resin is preferably smaller than that of the first resin. In particular, the value of “first resin Young's modulus/second resin Young's modulus” is preferably 80 or greater and more preferably 500 or greater. A larger value will produce a more satisfactory effect of reducing the difference in input load value and supporting the lower electrode 10 and upper electrode 20 by the bonding member 30. However, the upper limit for this value is about 150 N with possible combinations of resins in the bonding member 30. From the viewpoint of reducing the input load value around the bonding member 30, the Young's modulus of the second resin itself is preferably no greater than 20 MPa and more preferably no greater than 5 MPa.

The following resins are examples of first and second resins having suitable differences in hardness. For the first resin there may be mentioned phenol resins, melamine resins, urea resins, polyester resins, epoxy resins, polyimide resins, polyphenylsulfide resins, styrene-based resins (polystyrene), polyethersulfones, polyamideimide resins, polyetherimide resins and acrylic-based resins. The curable resins among these are preferably used in their cured state. A fully cured polycarbonate or polyacetal may also be used as the first resin. Examples of acrylic resins include 140 (Young's modulus: 26.09 MPa), 53H (Young's modulus: 872.70 MPa), 122P (Young's modulus: 444.25 MPa), 512 (Young's modulus: 106.85 MPa) and 1100H (Young's modulus: 1669.97 MPa), by Negami Chemical Industrial Co., Ltd. An example of an epoxy resin is AE-100 (Young's modulus: 2621.0 MPa) by Ajinomoto Fine-Techno.

The second resin may be a silicone resin, polyurethane resin, olefin-based resin (polyethylene, polypropylene, polybutylene or the like), styrene-based resin (acrylonitrile-butadiene-styrene), polyamide-based resin (nylon 6), polyurethane or acrylic-based resin, or a rubber compound. An example of a silicone resin is SE1740 A&B (Young's modulus: ≦20 MPa) by Toray/Dow Corning Silicone, Inc., and an example of a polyurethane resin is WD-720 (Young's modulus: ≦5 MPa) by Mitsui Chemical Polyurethane Co., Ltd.

When the first and second resins have a wide range of Young's modulus values even for the same type of resin, such as in the case of the acrylic resins mentioned above, similar resins with different hardnesses may be used in combination. With a curable resin, for example, a hard one with a high polymerization degree and high crosslinking degree may be used as the first resin, and a relatively soft one with a lower polymerization degree and crosslinking degree may be used as the second resin. Even when different types of resins are used as the first and second resins, the polymerization degrees and crosslinking degrees may be adjusted to obtain differences in hardness. For a curable resin, the polymerization degree and crosslinking degree can be controlled by appropriately adjusting the extent of heating or light exposure.

The hardnesses of the first and second resins can also be adjusted by adding components other than the resins. For example, the first and second resins will normally be harder if they also contain a filler, and the amount of such a filler can be adjusted to obtain the desired hardnesses for the first and second resins. The filler may be added only to either the first resin or second resin, or it may be added to both in different amounts. As fillers there may be mentioned inorganic oxide particles of titanium oxide or zinc oxide, resin powders, or monofilaments of glass fibers or carbon fibers.

The touch panel 100 having the construction described above can be fabricated, for example, by preparing the lower electrode 10 and upper electrode 20, forming the bonding member 30 on either or both their transparent conductive layers (14 or 24), and then attaching the lower electrode 10 and upper electrode 20 with the bonding member 30 sandwiched between the transparent conductive layers 14, 24.

The lower electrode 10 can be obtained by preparing the transparent base 12 and forming the transparent conductive layer 14 on it. Formation of the transparent conductive layer 14 on the transparent base 12 may be accomplished as appropriate depending on the structural material of the transparent conductive layer 14. For example, an ITO layer may be formed by a physical build-up method such as vapor deposition or sputtering. For a layer having transparent conductive particles fixed in the resin, the layer may be formed by dispersing the particles in a solvent, coating the solution onto the transparent base 12 by a prescribed method, and drying. The upper electrode 20 may be produced in the same manner.

The method for forming the bonding member 30 on the transparent conductive layer 14, 24 of the lower electrode 10 or upper electrode 20 may be the following. First, the first resin for formation of the first adhesive layer 32 is coated onto prescribed areas of the transparent conductive layer 14 or 24. If the first resin is a curable resin, it may be coated after dissolution in a solvent or the like before it is cured. The coating may be accomplished using a dispenser, for example.

When the first adhesive layer 32 is formed having an arched widthwise cross-section as described above, the coating solution containing the first resin may be banked into arches using the dispenser. After coating with the dispenser, arches may be aimed using a die or by cutting. As an alternative to coating, the first resin may be situated by first working it into arch shapes and then placing it over the transparent conductive layer 14 or 24.

Next, if the first resin is a curable resin, it may be cured to form the first adhesive layer 32. The curing may be accomplished by heating or photoirradiation, depending on the type of resin. The first adhesive layer 32 may also be formed by first curing the first resin and then working it into the desired shape by cutting or the like.

The second resin for formation of the second adhesive layer 34 is coated onto the first adhesive layer 32 using a dispenser or the like, while it is dispersed in a solvent, for example. The coating is carried out so that the first adhesive layer 32 is covered by the second resin. This will situate the second resin so as to fill the sections of reduced width when the first adhesive layer 32 has been formed into arches, for example.

Next, if the second resin is a curable resin, it may be cured to form the second adhesive layer 34. The bonding member 30 can be formed in this manner. A touch panel 100 is then obtained by attaching the lower electrode 10 and the upper electrode 20 as described above. The first resin and second resin do not need to be cured separately, and the first resin and second resin may be cured together after coating, for example. They may even be cured after attaching the lower electrode 10 and upper electrode 20.

The preferred embodiments of the touch panel of the invention described above are not intended to be limitative. For example, instead of having the second adhesive layer 34 provided on the first adhesive layer 32 that has been formed into arches, the bonding member 30 may be the following type.

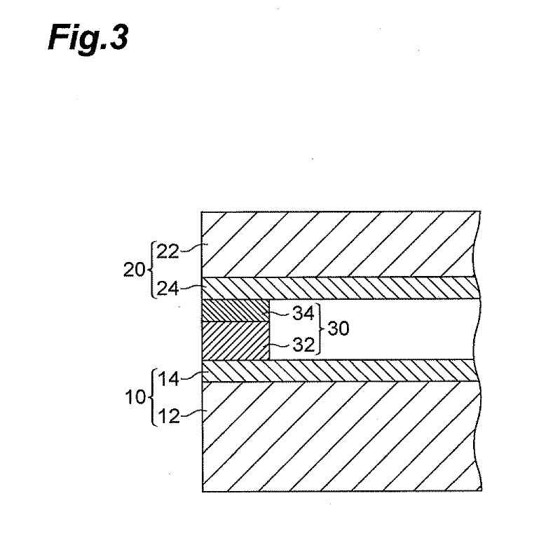

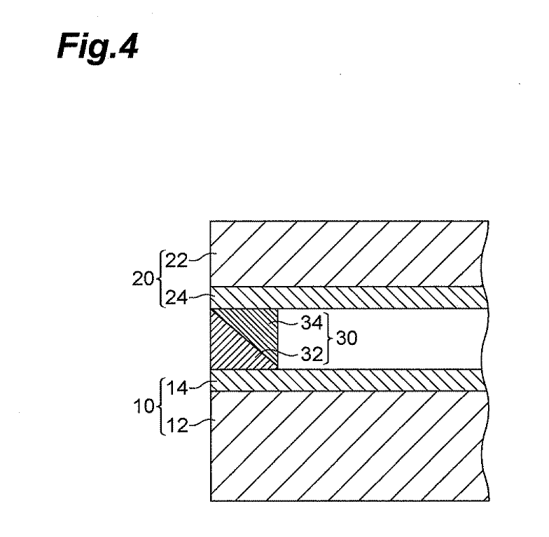

FIGS. 3 and 4 are a cross-sectional magnified views of the section around the bonding member of the touch panel according to another embodiment. In the example shown in FIG. 3, the bonding member 30 has a two-layer structure with separate formation of the first adhesive layer 32 on the lower electrode 10 side and the second adhesive layer 34 on the upper electrode 20 side. Even with such a structure in which the first adhesive layer 32 and second adhesive layer 34 are laminated in parallel, the distance between the lower electrode 10 and the upper electrode 20 in the hard first adhesive layer 32 can be kept to an absolute minimum while allowing satisfactory deformation of the electrodes in the soft second adhesive layer 34 in response to bending.

In the example shown in FIG. 4, the first adhesive layer 32 of the bonding member 30 is formed so that the thickness decreases from the outside to the inside of the touch panel 100. Specifically, it has a form in which the widthwise cross-section of the first adhesive layer 32 narrows from the lower electrode 10 toward the upper electrode 20 on the edge sides of the touch panel. The second adhesive layer 34 is formed in such a manner that it fills the sections where the thickness of the first adhesive layer 32 has been reduced (the width has been narrowed).

With such a construction, the hard first adhesive layer 32 contacts with both the lower electrode 10 and the upper electrode 20, thus satisfactorily supporting the electrodes and preventing their contact in the absence of pressing force. Since the contact area with the first adhesive layer 32 is reduced and the contact sites are on the edges on the upper electrode 20 side, the upper electrode 20 bends satisfactorily when pressed. In this case as well, since the bonding member 30 has the soft second adhesive layer 34 filling the sections where the first adhesive layer 32 width is narrowed, it can satisfactorily bond with the upper electrode 20 without inhibiting bending of the upper electrode 20.

Incidentally, the bonding member 30 may have a different structure so long as it comprises at least the first adhesive layer 32 and the softer second adhesive layer 34. For example, the cross-section of the first adhesive layer 32 may have a shape that protrudes only on part of the upper electrode 20 side, or it may be a trapezoid shape with a narrow width on the upper electrode 20 side. The second adhesive layer 34 may also run over the regions where it fills the section of reduced width of the first adhesive layer 32.

The bonding member 30 may also have another adhesive layer in addition to the first adhesive layer 32 and second adhesive layer 34. For example, the bonding member 30 may have a structure with 3 or more adhesive layers composed of resins with different hardnesses.

### EXAMPLES

The present invention will now be explained in greater detail through examples, with the understanding that these examples are in no way limitative on the invention.

### Fabrication of Touch Panels

### Examples 1-4

First there were prepared a transparent base (ARTON) made of a norbornane resin and provided with a transparent conductive layer made of tin-doped indium oxide, as the lower electrode, and a transparent base made of polyethylene terephthalate (PET) and provided with a transparent conductive layer made of tin-doped indium oxide, as the upper electrode. A dot spacer composed of different acrylic-based resins was formed on the transparent conductive layer of the lower electrode. An extraction electrode made of Ag was formed on each of the transparent conductive layers of the lower electrode and upper electrode, by screen printing.

Next, the first resin was coated along the perimeter on the transparent conductive layer of the lower electrode using a dispenser, in a manner creating arches in the widthwise cross-section. The first resin was dried and cured for 15 minutes at 100° C. to form a first adhesive layer. After coating the second resin with a dispenser to cover the first adhesive layer, it was dried for 15 minutes at 100° C. and cured to form a second adhesive layer. This resulted in a bonding member having a first adhesive layer with arches, covered by the second adhesive layer.

The combinations of the first resin and second resin in Examples 1-4 were as follows.

(1) Example 1 First resin: epoxy resin (AE-100, product of Ajinomoto Fine-Techno, Young's modulus upon curing: 2621 MPa); second resin: urethane resin (WD-720, product of Mitsui Chemical Polyurethane Co., Ltd., Young's modulus upon curing: ≦5 MPa).
(2) Example 2 First resin: epoxy resin (AE-100, product of Ajinomoto Fine-Techno, Young's modulus upon curing: 2621 MPa); second resin: silicone resin (SE-1740, product of Toray/Dow Corning Silicone, Inc., Young's modulus upon curing: 20 MPa).
(3) Example 3 First resin: acrylic resin (122P, product of Negami Chemical Industrial Co., Ltd., Young's modulus upon curing: 444.25 MPa); second resin: urethane resin (WD-720, product of Mitsui Chemical Polyurethane Co., Ltd., Young's modulus upon curing: ≦5 MPa).
(4) Example 4 First resin: filler-containing acrylic resin (53H, product of Negami Chemical Industrial Co., Ltd., Young's modulus upon curing: 1910 MPa, filler content: 20%); second resin: urethane resin (WD-720, product of Mitsui Chemical Polyurethane Co., Ltd., Young's modulus upon curing: ≦5 MPa).

The lower electrode and upper electrode were then placed together with their transparent conductive layers facing each other and attached via the bonding member. The stack was pressed so that the top parts of the first adhesive layer arches of the bonding member formed on the lower electrode contacted the transparent conductive layer of the upper electrode. A touch panel having the structure shown in FIG. 1 was thus obtained.

### Comparative Example 1

A touch panel was fabricated in the same manner as Examples 1-4, except that the bonding member had a monolayer structure employing only an acrylic resin, and it was formed to approximately the same width and height.

### Comparative Example 2

A touch panel was fabricated in the same manner as Examples 1-4, except that the bonding member employed only an acrylic resin, the width was halved, and formation was toward the edge sides.

[Evaluation of Touch Panels]

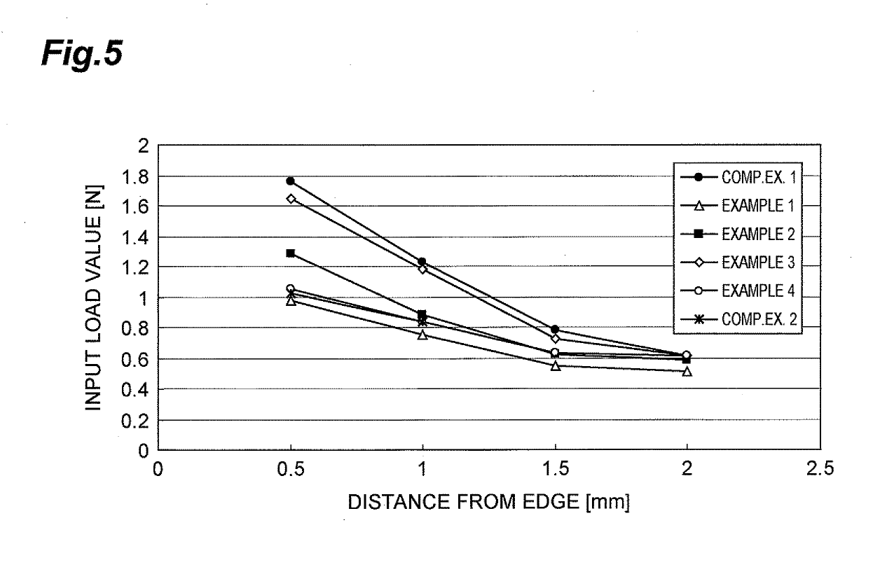

Each of the obtained touch panels was used for measurement of the force necessary to contact the upper electrode and lower electrode when the upper electrode was pressed at sections with different distances from the edges (input load value (N)). Pressing was with a polyacetal resin touch pen having a 0.8 R tip shape, and contact between the upper electrode and lower electrode was confirmed using a Digital Multimeter, with the pressure being measured by a Digital Force Analyzer (product of Imada Co., Ltd.). The results are summarized in Table 1 and FIG. 5. FIG. 5 is a graph plotting the required input load value with respect to distance from the edge. Table 1 shows the ratios of hardnesses of the first resin and second resin of the bonding member (first resin Young's modulus/second resin Young's modulus).

TABLE 1

| | Ratio of hardness of | Input load value | | | |
|---|---|---|---|---|---|
| | first resin and second | Distance from edge (mm) | | | |
| | resin | 0.5 | 1.0 | 1.5 | 2.0 |
| Example 1 | 524 | 0.98 | 0.75 | 0.55 | 0.51 |
| Example 2 | 131 | 1.28 | 0.88 | 0.62 | 0.59 |
| Example 3 | 88.9 | 1.65 | 1.18 | 0.73 | 0.61 |
| Example 4 | 382 | 1.05 | 0.84 | 0.63 | 0.61 |
| Comp. Ex. 1 | — | 1.755 | 1.231 | 0.782 | 0.612 |
| Comp. Ex. 2 | — | 1.044 | 0.855 | — | — |

As seen in Table 1 and FIG. 5, the touch panels of Examples 1-4, which had two-layer bonding members comprising first and second adhesive layers with different hardnesses, exhibited lower increase in input load value from the center (2.0 mm from the edge) toward the edge side (0.5 mm), compared to Comparative Example 1 which had only an acrylic monolayer formed as the bonding member.

Also, in Examples 1-4, no contact occurred at any region of the touch panel between the lower electrode and upper electrode in the absence of pressing force. In contrast, the touch panel of Comparative Example 2, which had a bonding member of narrow width and fumed on the edge sides, exhibited a lower input load value at the edge sides but also had contact between the lower electrode and upper electrode in the absence of pressing force at center locations beginning 1.5 mm from the edges, such that the input load value could not be measured at those sections.

What is claimed is:

1. A touch panel having a lower electrode comprising a first transparent base and a first transparent conductive layer laminated on the first transparent base, and an upper electrode comprising a second transparent base and a second transparent conductive layer laminated on the second transparent base, which are mutually opposing in such a manner that the first transparent conductive layer and second transparent conductive layer face each other, wherein
the lower electrode and upper electrode are laid facing each other partially sandwiching a bonding member, and
the bonding member comprises a first adhesive layer composed of a first resin, and a second adhesive layer composed of a second resin that is softer than the first resin.

2. A touch panel according to claim 1, wherein the bonding member is formed so that the first adhesive layer and second adhesive layer are separated in the thickness direction.

3. A touch panel according to claim 1, wherein the first adhesive layer has a smaller width on either the lower electrode or upper electrode, as compared to the other one, in a cross-section along the widthwise direction of the bonding member, and
the second adhesive layer is formed in a manner filling at least the section of reduced width of the first adhesive layer in that cross-section.

4. A touch panel according to claim 3, wherein the first adhesive layer is formed in such a manner that its thickness decreases from the outside toward the inside of the touch panel.

5. A touch panel according to claim 3, wherein the first adhesive layer has a shape with arches in the cross-section.
